(19) United States
(12) Patent Application Publication
(10) Pub. No.: US 2026/0153563 A1
(43) Pub. Date: Jun. 4, 2026

(54) CLOCK TAMPER DETECTOR AND METHOD FOR DETECTING A CLOCK TAMPERING EVENT

(71) Applicant: PUFsecurity CORPORATION, HSINCHU COUNTY (TW)

(72) Inventors: KAI-HSIN CHUANG, HSINCHU COUNTY (TW); SHENG-TSUNG WANG, HSINCHU COUNTY (TW)

(21) Appl. No.: 19/404,721

(22) Filed: Dec. 1, 2025

Related U.S. Application Data
(60) Provisional application No. 63/728,135, filed on Dec. 4, 2024.

(51) Int. Cl. G01R 31/317; G06F 1/04; H03K 19/20; H03K 21/10

(52) U.S. Cl. CPC G01R 31/31727; G06F 1/04; H03K 19/20; H03K 21/10

(57) ABSTRACT

The present application discloses a clock tamper detector. The clock tamper detector includes a clock terminal for receiving a system clock signal, a clock generator for generating a reference clock signal, an oscillator for generating an oscillation signal having a targeted frequency greater than a targeted frequency of the reference clock signal and a targeted frequency of the system clock signal, a control circuit for calibrating an operating frequency of the oscillation signal according to the reference clock signal in a calibration mode, a detection counter for counting a number of cycles of the oscillation signal that occur within each cycle of the system clock signal in a detection mode, and a comparison logic circuit for issuing an alarm signal at least when a difference between the number of cycles of the oscillation signal and a predetermined number code is greater than a threshold value in the detection mode.

### CROSS REFERENCE

This application claims the benefit of prior-filed U.S. provisional application No. 63/728,135, filed on December 04, 2024, which is incorporated by reference in its entirety.

### TECHNICAL FIELD

The present disclosure relates to clock tamper detector, and more particularly, to a clock tamper detector capable of detecting variations in a clock signal.

### DISCUSSION OF THE BACKGROUND

As electronic devices become increasingly integrated into daily life and critical infrastructure, the scope of electronic circuit applications has gradually expanded. Consequently, some malicious individuals have begun to attack electronic circuits in order to obtain important data that is transmitted or stored within them, raising concerns about data privacy and posing significant challenges to information and communication security.

One of the main vulnerability in circuits is the manipulation of clock signals. Attackers may attempt to alter the timing of the clock signals to disrupt normal operations or compromise sensitive data. For example, by increasing the clock frequency, an attacker can cause setup time violations, leading to data corruption or system malfunctions. Conversely, by slowing down the clock, the system may behave unpredictably or even allow attackers to weaken cryptographic mechanisms, making it easier to reach the sensitive data. Therefore, how to implement mechanisms that can monitor and identify unusual clock behavior has become a crucial issue in the field for maintaining the integrity and reliability of electronic systems.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a clock tamper detector. The clock tamper detector includes a clock terminal, a clock generator, an oscillator, a control circuit, a detection counter, and a comparison logic circuit. The clock terminal receives a system clock signal, and the clock generator generates a reference clock signal. The oscillator generates an oscillation signal having a targeted frequency greater than a targeted frequency of the reference clock signal and a targeted frequency of the system clock signal. In a calibration mode, the control circuit calibrates an operating frequency of the oscillation signal according to the reference clock signal, and in a detection mode after the calibration mode, the detection counter counts a first number of cycles of the oscillation signal that occur within each cycle of the system clock signal. In the detection mode, the comparison logic circuit issues an alarm signal at least when a difference between the first number of cycles of the oscillation signal and a first predetermined number code is greater than a first threshold value. The first predetermined number code is corresponding to an expected number of cycles of the oscillation signal that occur within each cycle of the system clock signal.

Another aspect of the present disclosure provides a method for detecting a clock tampering event. The method includes receiving a system clock signal, generating, by a clock generator, a reference clock signal, generating, by an oscillator, an oscillation signal having a targeted frequency greater than a targeted frequency of the reference clock signal and a targeted frequency of the system clock signal, calibrating an operating frequency of the oscillation signal according to the reference clock signal in a calibration mode, counting, by a detection counter, a first number of cycles of the oscillation signal that occur within each cycle of the system clock signal in a detection mode after the calibration mode, and issuing an alarm signal at least when a difference between the first number of cycles of the oscillation signal and a first predetermined number code is greater than a first threshold value in the detection mode. The first predetermined number code is corresponding to an expected number of cycles of the oscillation signal that occur within each cycle of the system clock signal.

### BRIEF DESCRIPTION OF THE PLOTTINGS

A more complete understanding of the present disclosure may be derived by referring to the detailed description and claims when considered in connection with the Figures, where like reference numbers refer to similar elements throughout the Figures.

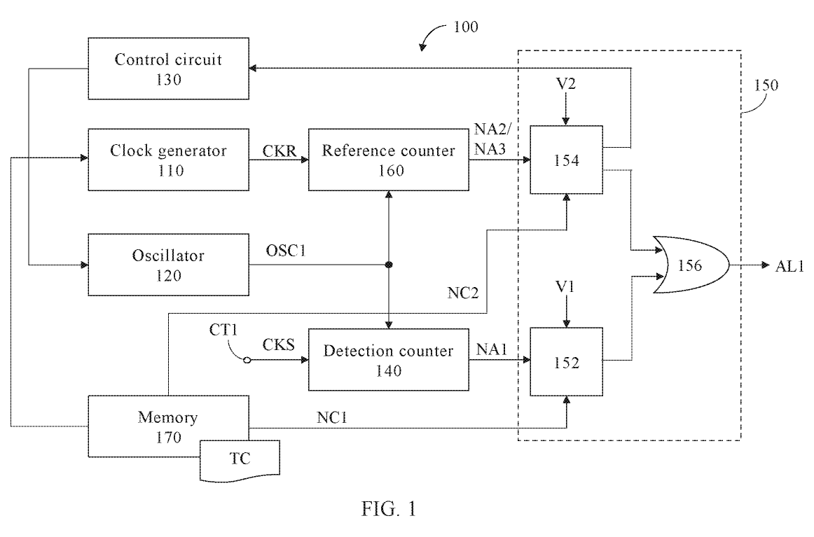

FIG. 1 shows a clock tamper detector according to one embodiment of the present disclosure.

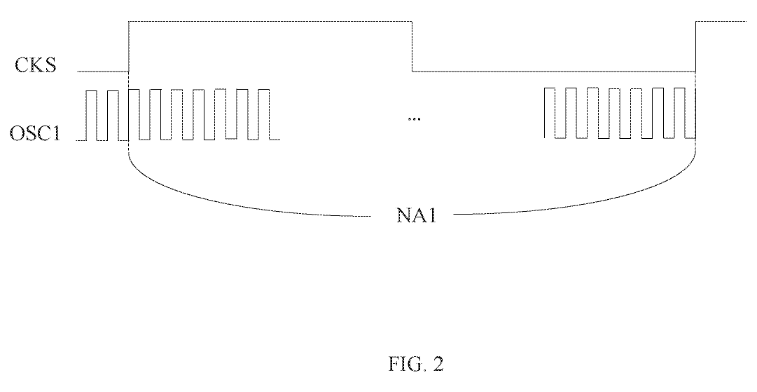

FIG. 2 shows waveforms of the oscillation signal and the system clock signal.

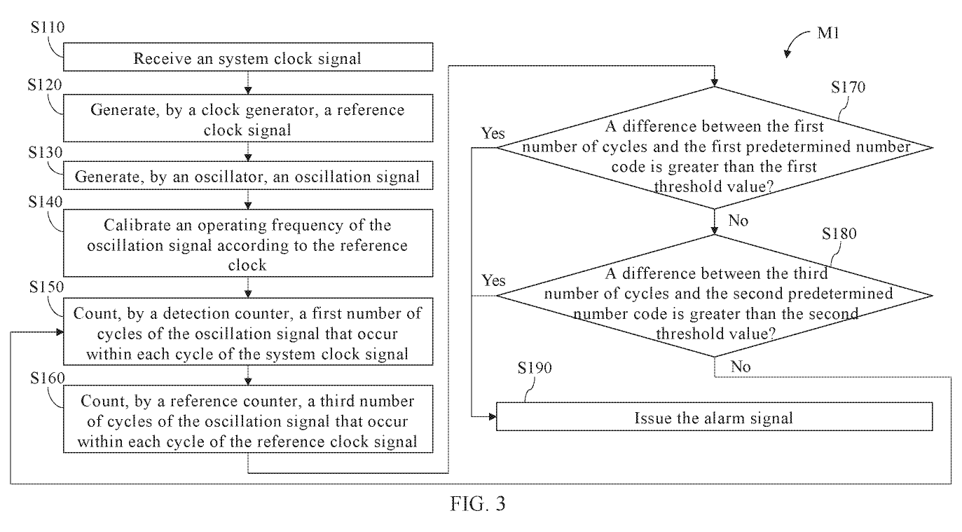

FIG. 3 shows a method for detecting a clock tampering event according to one embodiment of the present disclosure.

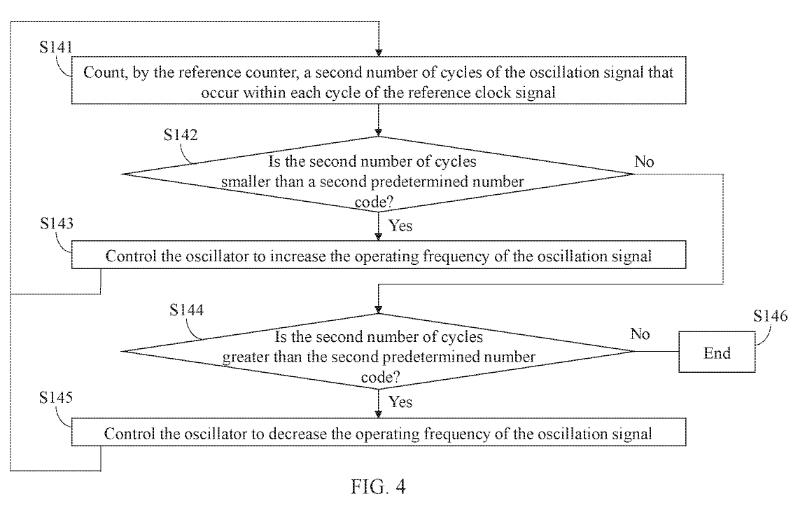

FIG. 4 shows steps performed in the calibration mode according to one embodiment of the present disclosure.

### DETAILED DESCRIPTION

FIG. 1 shows a clock tamper detector 100 according to one embodiment of the present disclosure. The clock tamper detector 100 includes a clock generator 110, an oscillator 120, a control circuit 130, a detection counter 140, a comparison logic circuit 150, and a reference counter 160.

In some embodiments, the clock tamper detector 100 may be incorporated within a circuit or system, such as a system on chip (SoC), and can be employed to monitor a system clock signal CKS required for the operations of the circuit or system. The clock tamper detector 100 is operable to detect abnormal variations in the system clock signal CKS, thereby facilitating the identification of potential tampering events associated with the system clock signal CKS.

The clock tamper detector 100 may adopt the oscillator 120 to generate an oscillation signal OSC1 having a rather high frequency to measure an operating frequency of the system clock signal CKS. The detection counter 140 and the comparison logic circuit 150 can be employed to check if the operating frequency of the system clock signal CKS has been changed from its targeted frequency beyond a threshold so as to detect the tampering events.

Since the oscillator 120 is able to generate the oscillation signal OSC1 having a frequency much higher than the operating frequency of the system clock signal CKS, the operating frequency of the system clock signal CKS can be accurately measured by the oscillation signal OSC1. Furthermore, the control circuit 130 and the reference counter 160 may be employed to calibrate the oscillation signal OSC1 according to a reference clock signal CKR generated by the clock generator 110, which can be designed to be insensitive to variations of voltages and/or temperature, thereby further improving the accuracy of the measurement of the system clock signal CKS. In other words, the clock tamper detector 100 may operate in two modes: a calibration mode for calibrating the oscillation signal OSC1, and a detection mode for identifying the tampering event of the system clock signal CKS according to the oscillation signal OSC1.

Specifically, the clock tamper detector 100 may include a clock terminal CT1 for receiving the system clock signal CKS. The oscillator 120 can generate the oscillation signal OSC1 having a targeted frequency greater than the targeted frequency of the system clock signal CKS. In some embodiments, the targeted frequency of the oscillation signal OSC1 can be at least ten times the targeted frequency of the system clock signal CKS. For example, the targeted frequency of the system clock signal CKS can be 40MHz, and the targeted frequency of the oscillation signal OSC1 can be 1GHz.

As the targeted frequencies of the oscillation signal OSC1 and the system clock signal CKS are determined, an expected number of cycles of the oscillation signal OSC1 that occur within each cycle of the system clock signal CKS operating at its targeted frequency (i.e., a ratio of the targeted frequency of the oscillation signal OSC1 to the targeted frequency of the system clock signal CKS) can be calculated and adopted as a reference in the detection mode for detecting variations of the actual frequency of the system clock signal CKS. For the sake of clarity in the present disclosure, the term "operating frequency" of a clock signal or an oscillation signal can refer to the actual frequency of such signal during its operation so as to be distinguished from its targeted frequency.

In the present embodiment, the expected number of cycles of the oscillation signal OSC1 that occur within each cycle of the system clock signal CKS operating at its targeted frequency can be stored as a predetermined number code NC1 in a memory device 170 of the clock tamper detector 100. For example, if the targeted frequency of the system clock signal CKS is 40MHz and the targeted frequency of the oscillation signal OSC1 is 1GHz, then the predetermined number code NC1 would be 25. In some embodiments, the memory device 170 can be a non-volatile memory device, so the predetermined number code NC1 can be stored stably even when the system or the circuit is not powered-on, and the predetermined number code NC1 can be loaded from the memory device 170 in the detection mode when needed.

In the detection mode, the detection counter 140 can count a number NA1 of cycles of the oscillation signal OSC1 that occur within each cycle of the system clock signal CKS operating at its targeted frequency. That is, the number NA1 can be deemed as an indication for the operating frequency of the system clock signal CKS with respect to the oscillation signal OSC1. FIG. 2 shows waveforms of the oscillation signal OSC1 and the system clock signal CKS. In such case, if the number NA1 of the cycles of the oscillation signal OSC1 counted by the detection counter 140 is greater than the predetermined number code NC1, it may imply that the operating frequency of the system clock signal CKS is lower than the targeted frequency of the system clock signal CKS. Conversely, if the number NA1 of the cycles of the oscillation signal OSC1 counted by the detection counter 140 is smaller than the predetermined number code NC1, it may imply that the operating frequency of the system clock signal CKS is higher than the targeted frequency of the system clock signal CKS.

In either case, if the difference between the number NA1 and the predetermined number code NC1 is greater than a threshold value V1, it may imply that the system clock signal CKS has been manipulated by an attack. For example, in some embodiments, the comparison logic circuit 150 can load the predetermined number code NC1 from the memory device 170, and can compare the number NA1 with the predetermined number code NC1. The comparison logic circuit 150 can issue an alarm signal AL1 when the difference between the number NA1 and the predetermined number code NC1 is greater than the threshold value V1. In some embodiments, the threshold value V1 can be adjusted according to the system’s need, and can be 0 if the system has a rather strict requirement for clock accuracy.

In some embodiments, before the clock tamper detector 100 enters the detection mode, the clock tamper detector 100 may operate in the calibration mode and may utilize the control circuit 130 and the reference counter 160 to calibrate the oscillator 120 so as to adjust the operating frequency of the oscillation signal OSC1 to be close to its targeted frequency.

In the present embodiment, while the system clock signal CKS is received from an external source, which may introduce various uncontrollable factors, the reference clock signal CKR is generated locally by the clock generator 110. Accordingly, the reference clock signal CKR can exhibit greater predictability and stability relative to the externally sourced system clock signal CKS. In some embodiments, a targeted frequency of the reference clock signal CKR can be determined according to the targeted frequency of the system clock signal CKS. In some embodiments, the targeted frequency of the reference clock signal CKR may be within a similar range of the targeted frequency of the system clock signal CKS. For example, the targeted frequency of the reference clock signal CKR can be within the range of ±20% of the targeted frequency of the system clock signal CKS so as to provide a better reference for the system clock signal CKS. However, the present disclosure is not limited. In some embodiments, a trim code TC for controlling the targeted frequency of the clock generator 110 can be stored in the memory device 170, so that when the clock tamper detector 100 is powered on or reset, the clock generator 110 can load the trim code TC from the memory device 170 to generate the reference clock signal CKR aiming at the targeted frequency.

Furthermore, the targeted frequency of the oscillation signal OSC1 can be greater than the targeted frequency of the reference clock signal CKR. In some embodiments, the targeted frequency of the oscillation signal OSC1 can be at least ten times the targeted frequency of the reference clock signal CKR. For example, the targeted frequency of the reference clock signal CKR can be 50MHz, and the targeted frequency of the oscillation signal OSC1 can be 1GHz. As the targeted frequency of the oscillation signal OSC1 and the targeted frequency of the reference clock signal CKR are determined, an expected number of cycles of the oscillation signal OSC1 that occur within each cycle of the reference clock signal CKR operating at its targeted frequency (i.e., a ratio of the targeted frequency of the oscillation signal OSC1 to the targeted frequency of the reference clock signal CKR) can be calculated and adopted as a reference for calibrating the oscillation signal OSC1 in the calibration mode. In the present embodiment, the expected number of cycles of the oscillation signal OSC1 that occur within each cycle of the reference clock signal CKR operating at its targeted frequency can be stored as a predetermined number code NC2 in the memory device 170. In the case that the targeted frequency of the reference clock signal CKS is 50MHz and the targeted frequency of the oscillation signal OSC1 is 1GHz, the predetermined number code NC2 would be 20.

In the calibration mode, the reference counter 160 can count a number NA2 of cycles of the oscillation signal OSC1 that occur within each cycle of the reference clock signal CKR. That is, the number NA2 can be deemed as an indication for the operating frequency of the oscillation signal OSC1 with respect to the reference clock signal CKR. In such case, if the number NA2 of the cycles of the oscillation signal OSC1 counted by the reference counter 160 is greater than the predetermined number code NC2, it may imply that the operating frequency of the oscillation signal OSC1 is higher than the targeted frequency of the oscillation signal OSC1, and the control circuit 130 can control the oscillator 120 to decrease the operating frequency of the oscillation signal OSC1. Conversely, if the number NA2 of the cycles of the oscillation signal OSC1 counted by the reference counter 160 is smaller than the predetermined number code NC2, it may imply that the operating frequency of the oscillation signal OSC1 is lower than the targeted frequency of the oscillation signal OSC1, and the control circuit 130 can control the oscillator 120 to increase the operating frequency of the oscillation signal OSC1. In some embodiments, the calibration can be determined to be completed when the control circuit 130 has stopped adjusting the oscillator 120 for a predetermined period of time. As a result, the oscillation signal OSC1 can be calibrated to have its operating frequency close to its targeted frequency according to the reference clock signal CKR, and thus can be adopted as a good reference for measuring the operating frequency of the system clock signal CKS. In some embodiments, the clock tamper detector 100 may enter the calibration mode whenever the system is powered on or reset, and may enter the detection mode after the control circuit 130 completes calibration.

In some embodiments, by properly designed, the clock generator 110 can be insensitive to variations of voltages and/or temperature, and thus, the operating frequency of the reference clock signal CKR can be pretty close to its targeted frequency, making it a good reference for calibrating the oscillation signal OSC1.

Furthermore, in some embodiments, the clock generator 110 may also be attacked, and thus, the clock tamper detector 100 may further detect the variation of the reference clock signal CKR in the detection mode so as to detect the tampering events associated with the reference clock signal CKR. Specifically, in the detection mode, the reference counter 160 may also count the number NA3 of cycles of the oscillation signal OSC1 that occur within each cycle of the reference clock signal CKR. That is, the number NA3 can be deemed as an indication for the operating frequency of the reference clock signal CKR with respect to oscillation signal OSC1. In such case, the comparison logic circuit 150 can, in the detection mode, issue the alarm signal AL1 when a difference between the number NA3 and the predetermined number code NC2 is greater than a threshold value V2 or when the difference between the number NA1 and the predetermined number code NC1 is greater than the threshold value V1. In other words, the clock tamper detector 100 can detect both the variations of the system clock signal CKS and the reference clock signal CKR, and issue the alarm signal AL1 when the variation of system clock signal CKS or the reference clock signal CKR is beyond an acceptable region.

In some embodiments, the comparison logic circuit 150 includes comparing circuits 152, 154, and an OR gate 156. The comparing circuit 152 can compare a difference between the number NA1 and the predetermined number code NC1 with the threshold value V1, and can issue a logic high voltage through its output terminal when the difference between the number NA1 and the predetermined number code NC1 is greater than the threshold value V1. The comparing circuit 154 can compare a difference between the number NA3 and the predetermined number code NC2 with the threshold value V2, and can issue a logic high voltage through its output terminal when the difference between the number NA3 and the predetermined number code NC2 is greater than the threshold value V2. In some embodiments, the threshold values V1 and V2 may also be stored in the memory device 170. However, the present disclosure is not limited thereto.

The output terminals of the comparing circuits 152 and 154 can be coupled to the input terminals of the OR gate 156, and the OR gate 156 can generate the alarm signal AL1 accordingly. In some embodiments, the comparing circuits 152 and 154 can be sequential circuits that are synchronized with the system clock signal CKS. In such case, a synchronization circuit (not shown) may be required to synchronize the counting result obtained by the reference counter 160 with the system clock signal CKS.

FIG. 3 shows a method M1 for detecting a clock tampering event according to one embodiment of the present disclosure. The method M1 includes steps S110-S190. In some embodiments, the method M1 can be applied to the clock tamper detector 100, however, the present disclosure is not limited thereto.

In step S110, the clock tamper detector 100 may receive the system clock signal CKS from the clock terminal CT1, and in step S120, the clock generator 110 may generate the reference clock signal CKR. In step S130, the oscillator 120 may generate the oscillation signal OSC1.

In the present embodiment, before the method M1 enters the detection mode to detect the tampering events of the system clock signal CKS, the method M1 may have the clock tamper detector 100 enter the calibration mode to calibrate the operating frequency of the oscillation signal OSC1 according to the reference clock signal CKR first in step S140.

FIG. 4 shows steps performed in the calibration mode according to one embodiment of the present disclosure. As shown in FIG. 4, in the calibration mode, the reference counter 160 may count the number NA2 of cycles of the oscillation signal OSC1 that occur within each cycle of the reference clock signal CKR (step S141). In the present embodiment, since the targeted frequencies of the oscillation signal OSC1 and the reference clock signal CKR are predetermined, the expected value of the number NA2 can also be calculated in advance and adopted as a reference for calibrating the oscillation signal OSC1. In some embodiment, the expected value of the number NA2 can be stored in the memory device 170 as the predetermined number code NC2.

In such case, in step S142, if the number NA2 is smaller than the predetermined number code NC2, it may imply that the operating frequency of the oscillation signal OSC1 is lower than its targeted frequency, and the control circuit 130 can control the oscillator 120 to increase the operating frequency of the oscillation signal OSC1 in step S143. Otherwise, in step S144, if the number NA2 is greater than the predetermined number code NC2, it may imply that the operating frequency of the oscillation signal OSC1 is higher than its targeted frequency, and the control circuit 130 can control the oscillator 120 to decrease the operating frequency of the oscillation signal OSC1 in step S145. The adjustment flow may be performed several times before the operating frequency of the oscillation signal OSC1 is calibrated to be close enough to its targeted frequency. In the present embodiment, if the oscillation signal OSC1 has not been changed by step S143 or step S145, it may imply that the operating frequency of the oscillation signal OSC1 is close enough to its targeted frequency, and the calibration can be ended in step S146. However, the present disclosure is not limited thereto. In some embodiments, the calibration in step S140 can be determined to be completed when the operating frequency of the oscillation signal OSC1 has not been adjusted for a predetermined time.

After the calibration is completed, the method M1 may have the clock tamper detector 100 enter the detection mode to detect the variations of the system clock signal CKS and the reference clock signal CKR in steps S150 to S190. In step S150, the detection counter 140 can count the number NA1 of cycles of the oscillation signal OSC1 that occur within each cycle of the system clock signal CKS. In the present embodiment, since the targeted frequencies of the oscillation signal OSC1 and the system clock signal CKS are predetermined, an expected value of the number NA1 can be calculated in advance and adopted as a reference for detecting the variation of the system clock signal CKS. In some embodiment, the expected value of the number NA1 can be stored in the memory device 170 as the predetermined number code NC1.

In such case, if the difference between the number NA1 and the predetermined number code NC1 is greater than the threshold value V1 in step S170, it may imply that the system clock signal CKS has been manipulated by an attack. Therefore, the comparison logic circuit 150 can issue the alarm signal AL1 in step S190 when the difference between the number NA1 and the predetermined number code NC1 is greater than the threshold value V1.

Furthermore, in step S160, the reference counter 160 can count the number NA3 of cycles of the oscillation signal OSC1 that occur within each cycle of the reference clock signal CKR. In the present embodiment, since the targeted frequencies of the oscillation signal OSC1 and the reference clock signal CKR are predetermined, an expected number of cycles of the oscillation signal OSC1 that occur within each cycle of the reference clock signal CKR operating at its targeted frequency can be calculated in advance and adopted as a reference for detecting the variation of the reference clock signal CKR. In some embodiment, the expected number of cycles of the oscillation signal OSC1 that occur within each cycle of the reference clock signal CKR operating at its targeted frequency can be stored in the memory device 170 as the predetermined number code NC2.

In such case, if the difference between the number NA3 and the predetermined number code NC2 is greater than the threshold value V2 in step S180, it may imply that the system clock signal CKS has been manipulated by an attack. Therefore, the comparison logic circuit 150 can issue an alarm signal AL1 in step S190 when the difference between the number NA3 and the predetermined number code NC2 is greater than the threshold value V2.

In some embodiments, if the clock tamper detector 100 is adopted to only detect the variation of the system clock signal CKS, then steps S160 and S180 may be omitted. In such case, the comparison logic circuit 150 may issue the alarm signal AL1 in step S190 according to the condition checked in step S170 without considering the condition of step S180.

In summary, the clock tamper detector and the method for detecting a clock tampering event provided by the embodiments of the present disclosure can adopt a local clock generator to calibrate an oscillation signal generated by an oscillator and adopt the oscillation signal to measure an operating frequency of the system clock signal. Since the oscillator is able to generate oscillation signals having high frequencies, the oscillation signal can be well-suited for accurately measuring the system clock signal. Furthermore, since the frequency of the oscillation signal can be calibrated by a local clock generator, the accuracy of the clock tamper detector and the method thereof can be further improved. Since both the reference clock signal and the system clock signal are susceptible to tampering, employing an additional clock signal, such as an oscillation signal, makes simultaneous tampering of all three clock signals considerably more difficult. As a result, utilizing these three clock signals significantly increases the credibility of the alarm signal, thereby enhancing the reliability and effectiveness of the tamper detection system.

What is claimed is:

1. A clock tamper detector comprising:
a clock terminal configured to receive a system clock signal;
a clock generator configured to generate a reference clock signal;
an oscillator configured to generate an oscillation signal having a targeted frequency greater than a targeted frequency of the reference clock signal and a targeted frequency of the system clock signal;
a control circuit, configured to, in a calibration mode, calibrate an operating frequency of the oscillation signal according to the reference clock signal with the targeted frequency;
a detection counter configured to, in a detection mode after the calibration mode, count a first number of cycles of the oscillation signal with the targeted frequency that occur within each cycle of the system clock signal; and
a comparison logic circuit configured to, in the detection mode, issue an alarm signal at least when a difference between the first number of cycles of the oscillation signal and a first predetermined number code corresponding to the targeted frequency of the system clock signal is greater than a first threshold value;
wherein the first predetermined number code is corresponding to an expected number of cycles of the oscillation signal that occur within each cycle of the system clock signal.

2. The clock tamper detector of claim 1 further comprising:
a reference counter configured to, in the calibration mode, count a second number of cycles of the oscillation signal that occur within each cycle of the reference clock signal, and the control circuit is configured to calibrate the operating frequency of the oscillation signal when the second number of cycles of the oscillation signal is different from a second predetermined number code corresponding to the targeted frequency of the reference clock signal.

3. The clock tamper detector of claim 2, wherein the control circuit is configured to control the oscillator to increase the operating frequency of the oscillation signal when the second number of cycles of the oscillation signal is smaller than the second predetermined number code corresponding to an expected number of cycles of the oscillation signal that occur within each cycle of the reference clock signal, and control the oscillator to decrease the operating frequency of the oscillation signal when the second number of cycles of the oscillation signal is greater than the second predetermined number code so as to calibrate the operating frequency of the oscillation signal according to the reference clock signal.

4. The clock tamper detector of claim 2, wherein the clock tamper detector enters the detection mode from the calibration mode after the control circuit finishes calibrating the operating frequency of the oscillation signal.

5. The clock tamper detector of claim 2, wherein the second predetermined number code is configured to indicate an expected number of cycles of the oscillation signal that occur within each cycle of the reference clock signal according to the targeted frequency of the reference clock signal.

6. The clock tamper detector of claim 2, wherein:
the reference counter is further configured to, in the detection mode, count a third number of cycles of the oscillation signal that occur within each cycle of the reference clock signal,
wherein the comparison logic circuit is configured to, in the detection mode, issue the alarm signal when a difference between the third number of cycles of the oscillation signal and the second predetermined number code is greater than a second threshold value or when the difference between the first number of cycles of the oscillation signal and the first predetermined number code is greater than the first threshold value.

7. The clock tamper detector of claim 2, further comprising:
a memory device configured to store the first predetermined number code, and the second predetermined number code.

8. The clock tamper detector of claim 7, wherein the memory device is a non-volatile memory device, and a trim code is stored in the memory device, and the clock generator, in the calibration mode, generates the reference clock signal with the targeted frequency according to the trim code.

9. The clock tamper detector of claim 1, wherein the targeted frequency of the oscillation signal is at least ten times the targeted frequency of the reference clock signal and the targeted frequency of the system clock signal.

10. The clock tamper detector of claim 1, wherein the first predetermined number code is configured to indicate an expected number of cycles of the oscillation signal that occur within each cycle of the system clock signal according to the targeted frequency of the system clock signal.

11. A method for detecting a clock tampering event comprising:
receiving a system clock signal;
generating, by a clock generator, a reference clock signal;
generating, by an oscillator, an oscillation signal having a targeted frequency greater than a targeted frequency of the reference clock signal and a targeted frequency of the system clock signal;
calibrating an operating frequency of the oscillation signal according to the reference clock signal with the targeted frequency in a calibration mode;
counting, by a detection counter, a first number of cycles of the oscillation signal with the targeted frequency that occur within each cycle of the system clock signal in a detection mode after the calibration mode; and
issuing an alarm signal at least when a difference between the first number of cycles of the oscillation signal and a first predetermined number code corresponding to the targeted frequency of the system clock signal is greater than a first threshold value in the detection mode,
wherein the first predetermined number code is corresponding to an expected number of cycles of the oscillation signal that occur within each cycle of the system clock signal.

12. The method of claim 11, further comprising, in the calibration mode:
counting, by a reference counter, a second number of cycles of the oscillation signal that occur within each cycle of the reference clock signal,
controlling the oscillator to increase the operating frequency of the oscillation signal when the second number of cycles of the oscillation signal is smaller than a second predetermined number code corresponding to an expected number of cycles of the oscillation signal that occur within each cycle of the reference clock signal, and
controlling the oscillator to decrease the operating frequency of the oscillation signal when the second number of cycles of the oscillation signal is greater than the second predetermined number code so as to calibrate the operating frequency of the oscillation signal according to the reference clock signal.

13. The method of claim 12, wherein the step of calibrating the operating frequency of the oscillation signal according to the reference clock signal is completed when the operating frequency of the oscillation signal has not been adjusted for a predetermined time.

14. The method of claim 12, further comprising:
counting, by the reference counter, a third number of cycles of the oscillation signal that occur within each cycle of the reference clock signal in the detection mode;
wherein the step of issuing the alarm signal at least comprises, in the detection mode, issuing the alarm signal when a difference between the third number of cycles of the oscillation signal and the second predetermined number code is greater than a second threshold value or when the difference between the first number of cycles of the oscillation signal and the first predetermined number code is greater than the first threshold value.

15. The method of claim 12 further comprising:
determining the first predetermined number code according to the targeted frequency of the oscillation signal and the targeted frequency of the system clock signal;
determining the second predetermined number code according to the targeted frequency of the oscillation signal and the targeted frequency of the reference clock signal; and
storing the first predetermined number code and the second predetermined number code to a non-volatile memory device.

16. The method of claim 15, wherein the step of generating the reference clock signal comprises:
loading a trim code from the non-volatile memory device; and
generating the reference clock signal with the targeted frequency according to the trim code.

17. The method of claim 11, wherein the targeted frequency of the oscillation signal is at least ten times the targeted frequency of the reference clock signal and the targeted frequency of the system clock signal.
